(19) United States
(12) Patent Application Publication
(10) Pub. No.: US 2025/0364501 A1
(43) Pub. Date: Nov. 27, 2025

(54) PACKAGING STRUCTURE AND PACKAGING METHOD FOR KILOAMPERE-LEVEL SINGLE-SWITCH SIC POWER SEMICONDUCTOR MODULE

(71) Applicants: Huazhong University of Science and Technology, Wuhan (CN); Electric Power Research Institute of Guangdong Power Grid Co., Ltd., Guangzhou (CN)

(72) Inventors: Zhiqiang WANG, Wuhan (CN); Yimin ZHOU, Wuhan (CN); Lingqi TAN, Guangzhou (CN); Kai MA, Guangzhou (CN); Ying LI, Guangzhou (CN); Liantao JIANG, Guangzhou (CN)

(73) Assignees: Huazhong University of Science and Technology, Wuhan (CN); Electric Power Research Institute of Guangdong Power Grid Co., Ltd., Guangzhou (CN)

(21) Appl. No.: 19/216,637

(22) Filed: May 22, 2025

(30) Foreign Application Priority Data
May 24, 2024 (CN) 202410656814.4

(51) Int. Cl. H01L 25/07; H01L 21/48; H01L 21/56; H01L 23/00; H01L 23/053; H01L 23/29; H01L 23/373; H01L 23/473; H01L 23/492; H01L 23/498; H01L 23/538; H01L 25/18

(52) U.S. Cl. CPC H01L 25/072; H01L 21/4853; H01L 21/56; H01L 23/053; H01L 23/293; H01L 23/3735; H01L 23/473; H01L 23/4924; H01L 23/49838; H01L 23/5383; H01L 23/5385; H01L 24/45; H01L 24/48; H01L 25/18; H01L 2224/45147; H01L 2224/48225; H01L 2924/10272; H01L 2924/12032; H01L 2924/13091

(57) ABSTRACT

The present invention discloses a packaging structure for a kiloampere-level single-switch SiC power semiconductor module, primarily including components such as SiC chips, substrates, baseplate, power and signal terminals, integrated gate/Kelvin source resistors, and housing. The packaging structure proposed in this invention improves the electrothermal performance of multi-chip SiC power modules, reduces the size of the power module, and breaks through the limitations on the number of parallel-connected SiC chips. It significantly enhances the current capacity and power density of existing SiC power semiconductor modules, making it particularly suitable for 1.7 kV˜6.5 kV single-switch power semiconductor modules in high-power applications such as rail transit traction and flexible DC power transmission. Furthermore, the packaging structure proposed in this invention is compatible with conventional fabrication processes such as soldering, wire bonding, and potting encapsulation. The fabrication method is mature and suitable for large-scale engineering applications.

### CROSS-REFERENCE TO RELATED APPLICATIONS

The application claims priority to Chinese patent application No. 202410656814.4. filed on May 24, 2024, the entire contents of which are incorporated herein by reference.

### TECHNICAL FIELD

The present invention relates to the technical field of semiconductors, and particularly relates to a packaging structure and a packaging method for a kiloampere-level single-switch SiC power semiconductor module.

### BACKGROUND

High-capacity power semiconductor modules, as key components of power electronic equipment, are widely used in high-power applications such as rail transit, wind power generation, and flexible DC power transmission. Currently, silicon (Si)-based power semiconductor modules have gradually approached material theoretical limits, becoming a main bottleneck in improving equipment performance. As a representative of wide-bandgap power semiconductors, silicon carbide (SiC) exhibits comprehensive performance advantages over Si, including higher breakdown voltage, lower switching losses, and higher operating junction temperatures, demonstrating broad application prospects. Limited by the current rating of a single chip, high-capacity SiC power semiconductor modules are typically composed of multiple chips connected in parallel. However, existing 1.7 kV˜6.5 kV SiC power semiconductor modules generally have low current ratings, making it difficult to meet the high-power application requirements.

Currently, there are no commercial products for kiloampere-level (current capacity exceeding 1000 A) single-switch SiC power semiconductor modules on the market, and corresponding packaging structures remain unexplored. Meanwhile, existing commercial kiloampere-level single-switch Si IGBT power semiconductor modules suffer from drawbacks such as a large size, a low power density, poor static/dynamic parallel current-sharing performance, and inadequate thermal dissipation performance, rendering them unsuitable for high-speed switching SiC chips. Given this, this invention proposes for the first time a novel packaging structure for 1.7 kV˜6.5 kV kiloampere-level single-switch SiC power semiconductor modules, filling the technical gap in this field.

Through the above analysis, the problems and shortcomings of the existing technologies are summarized as follows.
1. Currently, there are no commercial products for 1.7 kV˜6.5 kV kiloampere-level single-switch SiC power semiconductor modules on the market, and corresponding packaging structures of the 1.7 kV˜6.5 kV kiloampere-level single-switch SiC power semiconductor modules remain unexplored.
2. Existing commercial kiloampere-level single-switch Si IGBT module packaging structures suffer from drawbacks such as a large size, a low power density, poor static/dynamic parallel current-sharing performance, and inadequate thermal dissipation performance, making the existing commercial kiloampere-level single-switch Si IGBT module packaging structures unsuitable for high-speed switching SiC chips.

### SUMMARY

To address the problems in existing technologies, the present invention provides a packaging structure for a kiloampere-level single-switch SiC power semiconductor module.

The invention is implemented as follows: a packaging structure for a kiloampere-level single-switch SiC power semiconductor module, including:
multiple source power terminals and drain power terminals, distributed on multiple power DBC substrates, for providing power output and input of the module;
multiple parallel-connected SiC chips located on the same or different power DBC substrates, with each chip connected to the corresponding source power terminal via the power source bonding wire of each chip and to the corresponding drain power terminal via the drain copper region;
a signal DBC substrate, equipped with Kelvin source signal terminals, gate signal terminals, and Kelvin drain signal terminals, for receiving and transmitting module control signals;
a baseplate, fixedly connected to the above power DBC substrates and the signal DBC substrate, for effectively conducting heat generated by the SiC chips and ensuring high-reliability operation of the module;
a housing, together with potting silicone gel, encapsulates and protects all the above components, ensuring electrical insulation, providing mechanical support, preventing external contamination, and enabling long-term, reliable operation of the module.

Specifically, the packaging structure for the SiC power semiconductor module includes six power DBC substrates, with each power DBC substrate provided with n parallel-connected SiC chips (where n≥6), resulting in a total of 6×n (≥36) parallel-connected SiC chips in the entire module.

Further, the power DBC substrate includes drain, power source, Kelvin source, and gate copper regions. The drain copper region is U-shaped, with an opening of the drain copper region enclosing a rectangular power source copper region. The parallel-connected SiC chips are evenly spaced on the drain copper region (with n/2 chips arranged on each side of the drain copper region), symmetrically distributed about the vertical centerline of the U-shape. The gate and Kelvin source copper regions are also U-shaped, with openings of the gate and Kelvin source copper regions oriented opposite to the drain copper region and enclosing the entire drain-source copper region.

Further, a gate pad of each SiC chip is connected in series with an integrated gate resistor via a bonding wire. Multiple sets of split gate copper regions connected to the integrated gate resistor may be arranged along two straight lines or a single straight line, with electrical interconnection achieved through long bonding wires with continuous landing points. Additionally, when the Kelvin circulating current is large, the Kelvin source bonding wire of each SiC chip needs to be connected in series with a Kelvin source resistor, arranged in the same manner as the integrated gate resistor.

Further, the power source bonding wires of the parallel-connected SiC chips and the gate and Kelvin source bonding wires are bonded in opposite directions (180° difference), thereby decoupling a drive loop and a power loop, minimizing an impact of common-source parasitic inductance, and fully leveraging a high switching speed advantage of SiC chips.

Further, a common drain current convergence point for the parallel-connected SiC chips on the power DBC substrate is located along the vertical centerline of the drain copper region, while the common source convergence point is near the center of the power source copper region. The length and angle of the power source bonding wires for each parallel-connected SiC chip are precisely adjusted to improve static/dynamic current-sharing performance in multi-chip parallel operation.

Further, the drain and source power terminals are symmetrically structured and placed at the common drain and common source convergence points of two power DBC substrates, respectively, forming one “sub-switch” structure.

Further, three “sub-switch” structures may be formed by arranging one “sub-switch” structure at equal intervals. The gate, Kelvin source, and Kelvin drain signal terminals are placed on three identical signal DBC substrates. Both the signal DBC substrate and the power DBC substrate are three-layer structures (an upper copper layer, a ceramic layer, and a lower copper layer) and are connected to the baseplate. Moreover, drive loops of all parallel-connected SiC chips are connected to the gate and Kelvin source signal terminal via copper leads or bonding wires, forming an electrical connection of the drive loops. The Kelvin drain signal terminal and the DBC substrate are also connected to the drain copper region of the power DBC substrate via bonding wires.

Further, the SiC chips in the kiloampere-level single-switch SiC power semiconductor module packaging structure may consist entirely of SiC MOSFET chips or a proportional combination of SiC MOSFET and SiC SBD chips (e.g., 2:1, 1:1).

Another objective of the invention is to provide a packaging method for the kiloampere-level single-switch SiC power semiconductor module, including the following steps:
S101: soldering or sintering SiC chips and integrated gate/Kelvin source resistors onto a power DBC substrate;
S102: performing wire bonding for the gate, Kelvin source, and power source bonding wires of the SiC chips;
S103: soldering the drain and source power terminals and the gate, Kelvin source, and Kelvin drain signal terminals onto the power DBC substrate and signal DBC substrate, respectively, while soldering or sintering the power DBC substrate and signal DBC substrate onto the baseplate;
S104: performing wire bonding for interconnecting bonding wires between DBC substrates;
S105: assembling a housing of the SiC power semiconductor module and performing potting encapsulation.

Based on technical solutions and addressed technical problems described above, the advantages and positive effects of the invention are analyzed as follows.

First, the packaging structure proposed in this invention is an innovative structure formed through precise adjustment, optimization, and comprehensive reconstruction of existing kiloampere-level single-switch Si IGBT power semiconductor module structures, particularly suitable for high-speed switching SiC chips. Compared to existing Si IGBT modules, this packaging structure achieves a smaller size, a higher power density, and superior static/dynamic current-sharing and thermal performance.
1. High current capacity: the proposed packaging structure includes six parallel-connected DBC substrates, each provided with SiC chips (n≥6), resulting in a total of 6×n (>36) parallel-connected SiC chips in the module. This breaks a limitation on the number of parallel chips in existing commercial SiC power semiconductor modules, significantly increasing the current capacity (≥1000 A) of the module.
2. Compact size and high-power density: leveraging the small size of SiC chips and combining compact chip layout design with optimized DBC substrate copper regions, the size of the power semiconductor module is reduced, effectively improving the power density of the power semiconductor module.
3. Low power loss: the use of Kelvin connections and reverse bonding technology decouples the drive loop and the power loop, fully leveraging the high switching speed advantage of SiC chips to reduce switching losses. Additionally, the large-scale parallel connection of chips helps reduce the conduction loss of the power semiconductor module.
4. Excellent static/dynamic current-sharing performance: in terms of power loop design, symmetrical current paths and parasitic inductance are achieved through coordinated optimization of chip layout, bonding wire routing, common drain/source convergence point position, and drain/source power terminal structures. For the drive loop design, consistent and synchronized driving is ensured by integrating internal gate/Kelvin source resistors and symmetrically arranging gate-source signal terminals. As a result, the static/dynamic current-sharing performance of parallel-connected SiC chips is significantly improved.
5. Superior thermal performance: the use of a PinFin direct liquid-cooled baseplate significantly reduces the junction-to-fluid thermal resistance of parallel-connected SiC chips. Compared to the indirect cooling solution using printed thermal grease in commercial kiloampere-level single-switch Si IGBT power modules, the thermal performance of the SiC chips is greatly enhanced, improving the reliability of the SiC power semiconductor module.
6. Low packaging parasitic inductance and baseplate parasitic capacitance: the stacked arrangement of drain-source power terminals effectively reduces packaging parasitic inductance. Meanwhile, reducing the size of the DBC substrate minimizes baseplate parasitic capacitance, mitigating electromagnetic interference issues such as overshoot oscillation and common-mode current caused by parasitic parameters during high-speed switching of SiC chips, thereby enhancing module reliability.

Second, the primary technical problems addressed by this invention are how to reduce the packaging size of kiloampere-level single-switch SiC power semiconductor modules, increase the current capacity and power density, and improve static/dynamic current-sharing and thermal performance in multi-chip parallel operation.

The significant technical advancements achieved by this invention include:
1. Increased power density: leveraging the small size of SiC chips and combining compact chip layout design with optimized DBC substrate copper regions, the module size is reduced, effectively improving power density.
2. Enhanced current-handling capability: by paralleling multiple SiC chips (≥36) in a single module, the current-handling capacity is significantly increased to the kiloampere level (≥1000 A), meeting high-power application requirements. Additionally, optimized electrical connection design ensures uniform current distribution among parallel chips, improving electrical reliability and stability.
3. Optimized thermal management: the use of PinFin direct liquid-cooled baseplate technology effectively reduces the operating junction temperature of SiC chips, improving thermal stability and operational lifespan while achieving efficient thermal management.

Third, as supplementary evidence for the inventiveness of the claims, the following important aspects are highlighted:
(1) Expected benefits and commercial value of the technical solution of the present invention:

The proposed packaging structure is particularly suitable for 1.7 kV-6.5 kV kiloampere-level single-switch SiC power semiconductor modules in high-power applications such as rail transit traction and flexible DC power transmission. It can improve the power density and efficiency of traction inverters and flexible DC converter valves, reducing equipment construction, installation and maintenance costs, and electricity energy consumption, with significant economic, social, and ecological benefits.
(2) Filling a technical gap in the industry at home and abroad with the technical solution of the present invention:

This invention is the first to propose a novel packaging structure for 1.7 kV˜6.5 kV kiloampere-level single-switch SiC power semiconductor modules, filling a technical gap in this field.
(3) Solving long-standing technical challenges that people have been eager to address but have never been able to successfully resolve of the technical solution of the present invention:

The proposed packaging structure improves the electrothermal performance of multi-chip parallel operation, reduces power module size, and breaks the limitation on the number of parallel SiC chips, significantly increasing the current capacity and power density of existing SiC power semiconductor modules.

Fourth, the existing technical problems solved by the proposed packaging structure for kiloampere-level single-switch SiC power semiconductor modules and the resulting significant advancements include the following:

First, effectively increasing the current capacity of existing power semiconductor modules of the proposed packaging structure: existing commercial SiC power modules are limited by the number of parallel chips, typically offering low current capacity (<1000 A) and struggling to meet high-power demands. The proposed structure overcomes this limitation (≥36 parallel SiC chips), enabling higher current capacity of SiC power modules. This reduces power loss in electronic systems, improves energy conversion efficiency, and saves electricity.

Secondly, effectively increasing the power density of existing power semiconductor modules of the proposed packaging structure: existing commercial kiloampere-level single-switch Si IGBT modules suffer from a large size and a low power density. The proposed packaging structure leverages the small size of SiC chips and advanced packaging techniques (e.g., compact layout, optimized routing) to effectively reduce the packaging size of power semiconductor modules. This helps reduce the volume and weight of electronic systems, enhance system integration and lowering installation/maintenance costs.

Lastly, effectively improving the reliability of existing power semiconductor modules of the proposed packaging structure: optimized substrate layout and routing enhance static/dynamic current-sharing performance of the parallel SiC chips, mitigating uneven power distribution of the parallel SiC chips and improving thermal uniformity. The PinFin direct liquid-cooled baseplate reduces junction-to-fluid thermal resistance, enhancing heat dissipation of SiC power modules and ensuring reliability in harsh environments such as high temperatures and high pressures. Moreover, the proposed structure also provides functions such as mechanical support and contamination protection, further improving the system reliability of electronic systems.

The packaging structure for the kiloampere-level single-switch SiC power semiconductor module, through advanced SiC chips, packaging design, and optimization, effectively addresses existing technical challenges and achieves significant advancements in current capacity, efficiency, power density, and reliability. These advancements are crucial for promoting high-power applications such as flexible DC power transmission and electric locomotive traction.

### BRIEF DESCRIPTION OF DRAWINGS

FIG. 1 is a circuit topology diagram of a single-switch SiC power semiconductor module provided by an embodiment of the present invention.

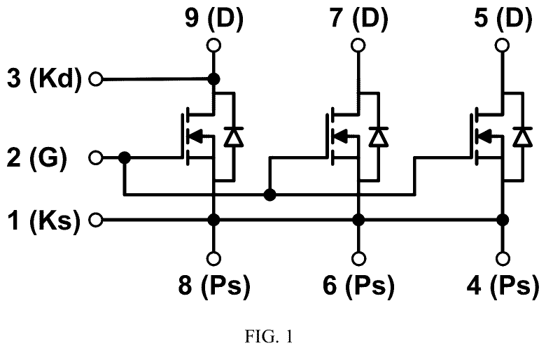

FIG. 2 is an overall packaging structure diagram of a 3.3 kV/2000 A SiC power semiconductor module provided by an embodiment of the present invention.

FIG. 3 is a packaging structure diagram of a first power DBC substrate of the 3.3 kV/2000 A SiC power semiconductor module provided by an embodiment of the present invention.

FIG. 4 is a structural diagram of drain and source power terminals provided by an embodiment of the present invention: (a) drain power terminal; (b) source power terminal.

FIG. 5 is a packaging structure diagram of one “sub-switch” of the 3.3 kV/2000 A SiC power semiconductor module provided by an embodiment of the present invention.

FIG. 6 is a structural diagram of the PinFin direct liquid-cooled baseplate (bottom surface) provided by an embodiment of the present invention.

FIG. 7 is a finished product structure diagram of the 3.3 kV/2000 A SiC power semiconductor module provided by an embodiment of the present invention.

FIG. 8 is a current waveform diagram of 36 parallel-connected SiC MOSFET chips provided by an embodiment of the present invention.

Numerals of packaging components in the figures:

1. Kelvin source signal terminal; 2. Gate signal terminal; 3. Kelvin drain signal terminal; 4. Source power terminal; 5. Drain power terminal; 6. Source power terminal; 7. Drain power terminal; 8. Source power terminal; 9. Drain power terminal; 10. First power DBC substrate; 11. Second power DBC substrate; 12. Signal DBC substrate; 13. PinFin direct liquid-cooled baseplate; 14. Drain copper region; 15. Power source copper region; 16. Kelvin source copper region; 17. Gate copper region; 18. SiC chip; 19. Integrated gate resistor; 20. Power source bonding wire; 21. Kelvin source bonding wire; 22. Gate bonding wire; 23. First interconnected gate bonding wire; 24. First interconnected Kelvin source bonding wire; 25. Second interconnected gate bonding wire; 26. Second interconnected Kelvin source bonding wire; 27. Third interconnected gate bonding wire; 28. Third interconnected Kelvin source bonding wire; 29. Interconnected Kelvin drain bonding wire; 30. Housing

### DETAILED DESCRIPTION OF THE EMBODIMENTS

To make objectives, technical solutions, and advantages of the present invention clearer, the following further details the invention with reference to specific embodiments. It should be understood that the described embodiments are merely illustrative of the invention and are not intended to limit its scope.

For a packaging structure of a kiloampere-level single-switch SiC power semiconductor module, two specific embodiments are provided here, demonstrating an application of this technology in different scenarios:

### Embodiment 1: MMC Flexible DC Power Transmission Converter Valve

High-voltage, high-capacity (kiloampere-level) power semiconductor modules are key components of modular multilevel converter (MMC) flexible DC power transmission converter valves in power systems, playing a critical role in power conversion and control. The kiloampere-level single-switch SiC power semiconductor module features low conduction voltage drop and high switching frequency, effectively reducing the size and weight of the equipment of the MMC flexible DC converter valve while improving efficiency. This offers significant advantages in applications such as offshore wind power flexible DC power transmission.
1. Power Conversion: in MMC flexible DC converter valves, the SiC power module is used to convert AC to DC (rectification mode) or DC to AC (inverter mode). The low switching and conduction losses of the SiC power module further enhance power conversion efficiency.
2. Module Integration: integrating the SiC power module into the MMC flexible DC converter valve reduces DC-side bus voltage ripple, lowers the capacitance requirement of bus capacitors, and thereby shrinks the size and weight of the converter valve, improving power density.
3. Thermal Management: an optimized direct liquid-cooled design reduces thermal resistance and extends operational lifespan.

### Advantages and Results:

Improved conversion efficiency: compared to traditional Si IGBT power modules, SiC power modules offer higher switching speeds and lower conduction voltage drops, enabling higher power conversion efficiency.

Higher power density: the high switching frequency of SiC power modules reduces the size and weight of bus capacitors, thereby decreasing the overall size and weight of the MMC flexible DC converter valve and improving the power density.

Extended operational lifespan: the optimized direct liquid-cooled design lowers the operating temperature of SiC chips and the entire module, prolonging the lifespan of the MMC flexible DC converter valve.

Reduced maintenance costs: the improved efficiency and power density of the MMC flexible DC converter valve reduce the installation, operation, and maintenance costs, particularly for offshore converter stations in offshore wind power transmission systems.

### Embodiment 2: High-Power Locomotive Traction Inverter

High-power locomotive traction inverters are widely used in rail transit systems such as high-speed trains, light rail, and subways. Their primary function is to convert DC power to three-phase AC power to drive three-phase asynchronous motors on locomotives. The kiloampere-level single-switch SiC power semiconductor module excels in such applications.
1. Power Conversion: the SiC power semiconductor module converts DC power to three-phase AC power in the locomotive traction inverter to achieve power conversion.
2. Module Integration: integrating the SiC power semiconductor module into the locomotive traction inverter reduces the weight of the locomotive traction inverter, improves power density, and lowers operational noise of the locomotive.
3. Thermal Management: Optimized direct liquid-cooled thermal dissipation reduces the operating temperature of the inverter, extending its lifespan.

### Advantages and Results:

Improved conversion efficiency: the SiC power module reduces power losses, enhancing the efficiency of the traction inverter.

Higher power density: the high switching frequency of the SiC power module decreases the weight of the traction inverter.

Extended operational lifespan: the optimized direct liquid cooling design prolongs the lifespan of the traction inverter.

Reduced maintenance costs: the improved efficiency and power density of the traction inverter lower operational and maintenance costs, saving energy consumption.

These two embodiments demonstrate that the kiloampere-level single-switch SiC power semiconductor module not only provides high-efficiency power conversion but also enhances the power density and operational lifespan of power electronic equipment.

The embodiments of the present invention provide a packaging structure for a kiloampere-level single-switch SiC power semiconductor module, including the following connections or positional relationships of components:
1. Kelvin source signal terminal, gate signal terminal, and Kelvin drain signal terminal are arranged on a signal DBC substrate for transmitting corresponding control signals.
2. Source power terminal and drain power terminal are arranged on the first and second power DBC substrates, respectively, for power output and input.
3. The first and second power DBC substrates are populated with SiC chips. These chips are connected to the source power terminal via power source bonding wires/copper regions, to the drain power terminal via drain copper regions, to the gate signal terminal via gate bonding wires/copper regions, and to the Kelvin source signal terminal via Kelvin source bonding wires/copper regions. Additionally, integrated gate resistors are placed on split gate copper regions and connected to the gate pads of the SiC chips via gate bonding wires.
4. The signal DBC substrate, the first power DBC substrate, and the second power DBC substrate are all fixed on a PinFin direct liquid-cooled baseplate.
5. Interconnect bonding wires (first, second, and third interconnect gate bonding wires and Kelvin source bonding wires) enable electrical interconnection of the drive circuits between SiC chips on different DBC substrates.
6. The entire packaging structure is installed in a housing, along with potting silicone gel, which provides electrical insulation, mechanical protection, and guards against external contamination.

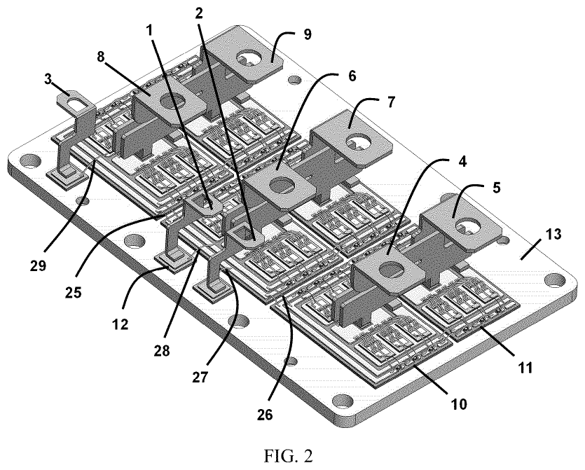

Specifically, the overall packaging structure of a 3.3 kV/2000 A single-switch SiC power semiconductor module is shown in FIG. 2, which mainly includes SiC chips, DBC ceramic substrates, PinFin direct liquid-cooled baseplate, power and signal terminals, integrated gate resistors, and the housing. The first power DBC substrate (10) and the second power DBC substrate (11) form two basic power units. These two power units are connected in parallel via drain power terminals (5/7/9) and source power terminals (4/6/8), forming one “sub-switch.” The entire SiC power semiconductor module includes three such “sub-switches.” The gate signal terminal (2), Kelvin source signal terminal (1), and Kelvin drain signal terminal (3) are respectively placed on three identical signal DBC substrates (12). All DBC substrates are connected to the same PinFin direct liquid-cooled baseplate (13). Further, each power DBC substrate is populated with six parallel SiC MOSFET chips (without SBDs), rated at 3.3 kV/66 A @ Tc=100° C. (from Microchip). Thus, the entire SiC power semiconductor module includes 36 parallel SiC MOSFET chips, achieving a current rating of 2376 A @ Tc=100° C. With a margin, the current capacity is designated as 2000 A @ Tc=100° C.

Below is a detailed explanation of the packaging structure design for the first power DBC substrate, one sub-switch, and the entire SiC power semiconductor module.

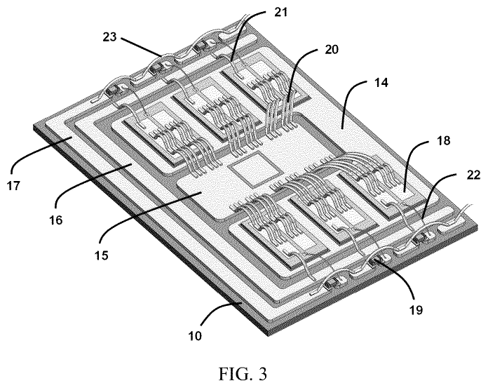

Firstly, as shown in FIG. 3, the first power DBC substrate includes: drain copper region (14), source copper region (15) and Kelvin source copper region (16). The drain copper region (14) is U-shaped, enclosing a rectangular power source copper region (15). The Kelvin source copper region (16) and the gate copper region (17) are arranged outward in a U-shape. Further, six parallel SiC MOSFET chips (18) are placed on the drain copper region (three on each side), symmetrical with respect to the central axis of the drain copper region. To mitigate parasitic parameter asymmetry in the drive circuit and suppress dynamic current imbalance and gate parasitic oscillation, the gate pad of each SiC MOSFET chip is connected in series with an integrated gate resistor (19) (5-15 Ω) via the gate bonding wire (22). To reduce the length of power DBC substrate, all split gate copper regions connected to the integrated gate resistors are arranged along the same straight line and form an electrical connection via the first interconnect gate bonding wire (23). Additionally, due to the small Kelvin circulating current, the Kelvin source bonding wire 21 is not connected in series with the Kelvin source resistor. Further, power source bonding wires (20) are bonded inward to the power source copper region. In contrast, gate bonding wires (22) and Kelvin source bonding wires (21) are bonded outward, whose bonding direction is opposite, decoupling the drive and power circuits. The common drain current collection point is at the centerline of the drain copper region, and the common source current collection point is slightly left of the center of the power source copper region, while the power source bonding wires (20) are bonded towards the common source current collection point. This design improves static and dynamic current sharing among the six parallel SiC MOSFET chips on the single power DBC substrate.

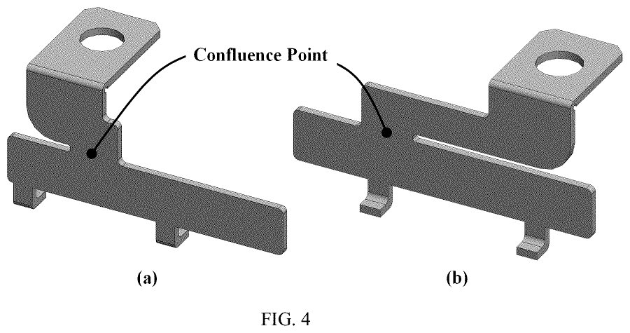

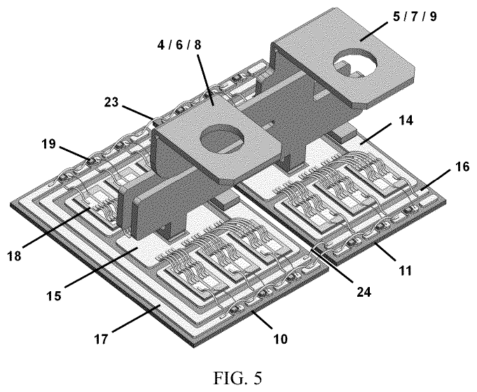

Secondly, as shown in FIG. 5, one sub-switch is formed by paralleling the first power DBC substrate (10) and the second power DBC substrate (11) via drain and source power terminals. It should be noted that the packaging structures of the second power DBC substrate (11) and the first power DBC substrate (10) are almost the same, the only difference lies in: the gate-source copper region of the second power DBC substrate lacks the U-shaped bottom edge to prevent drive circuit loop currents. Further, as shown in FIG. 4, the main structure of the drain and source power terminals uses a flat-plate structure (to minimize parasitic inductance through stacked configuration) with two support solder feet placed at common current collection points of the common drain and the common source. Due to the housing limitations, the entire structure of the drain power terminals (5/7/9) has difficulty being fully symmetrical, but the current collection point is symmetrical with respect to the two support solder feet. However, when the current collection point of the source power terminals (4/6/8) is located at the center of the two support solder feet, which is different from the drain power terminals, the entire dynamic current-sharing performance of 12 SiC chips which are parallel on the two DBC substrate is very bad, which is caused by the partial mutual-inductance between the drain and source terminals and the partial self-inductance in the source terminals, even though 6 chip of each power DBC substrate has dynamic current-sharing performance. Therefore, considering the static/dynamic current-sharing performance entirely, the current collection point of the source power terminal is shifted left to align with the current collection point of the drain terminal, optimizing dynamic current sharing for all 12 parallel chips. Further, electrical interconnection of drive circuits between the 12 parallel SiC chips is achieved via the first interconnect gate bonding wire (23) and the first interconnect Kelvin source bonding wire (24).

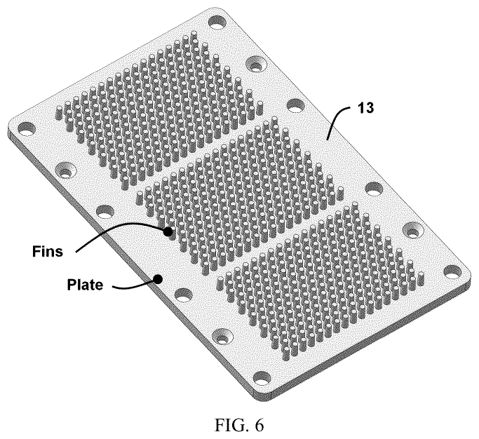

Thirdly, the packaging structure for the entire SiC power semiconductor module is as shown in FIG. 2, three sub-switches are arranged at equal intervals (e.g., 2 mm) according to a predetermined spacing in one sub-switch. The gate signal terminal (2), Kelvin source signal terminal (1), and Kelvin drain signal terminal (3) are placed on three identical signal DBC substrates (12). All DBC substrates are soldered to the PinFin direct liquid-cooled baseplate (13) (as shown in FIG. 6). Additionally, for the 3.3 kV/2000 A @ Tc=100° C. rating of the SiC power module designed in the embodiment, the thickness of the copper layer of the DBC substrate is 0.4 mm, and the ceramic layer is 1 mm AlN for sufficient current capacity and electrical insulation. The gate and Kelvin source signal terminals are symmetrically placed at the module's center to ensure that the drive circuit of the three sub-switches is symmetrical. The Kelvin drain signal terminal (3) is placed on one side of the module and connected to the drain copper region via an interconnect Kelvin drain bonding wire (29), enabling functions like desaturation protection, overvoltage monitoring, and junction temperature monitoring of the chips. Moreover, the gate and source circuits of all 36 SiC MOSFET chips in the three sub-switches are connected to the gate and source signal terminals (2/1) via the first, second, and third interconnected gate bonding wires (23-28) and interconnected Kelvin source bonding wires, achieving the electricity connection of the drive circuits.

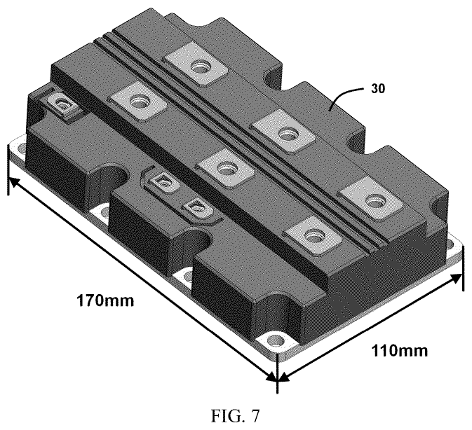

Lastly, the 3.3 kV/2000 A SiC power semiconductor module with assembled housing (as shown in FIG. 7) has dimensions of approximately 170×110 mm, 30% smaller than commercial kiloampere-level single-switch Si IGBT modules (190×140 mm), significantly improving the power density.

Based on the packaging structure for a kiloampere-level single-switch SiC power semiconductor module provided by the present invention, the present invention provides a 3.3 kV/2000 A SiC power semiconductor module, which has the advantages such as high capacity, small size, high power density and good static/dynamic current-sharing performance and thermal performance and this represents the highest-current-capacity and highest-power-rated SiC power semiconductor module up to now in the world, providing robust technical support for high-power applications such as rail transit traction and flexible DC power transmission.

The packaging structure for a kiloampere-level single-switch SiC power semiconductor module provided by the present invention mainly addresses key challenges in existing power semiconductor packaging technologies, such as a large size, a low power density, limited current capacity, and poor thermal performance. The working principle is specifically the following.
1. Layout Design: the packaging structure includes multiple power DBC substrates, each with multiple SiC chips, which are parallel via power terminals, forming multiple “sub-switches” to increase the current handling ability of the module. Additionally, optimized chip placement and DBC copper regions reduce the power semiconductor module's size and improve the module's power density.
2. Wiring Design: optimized electrical connections (such as bonding wires, current collection points, and configuration of terminals) ensure balanced current distribution. Additionally, reverse bonding decouples drive and power loop circuits, improving switching speed of the module and reducing electromagnetic interference (EMI).
3. Thermal Design: the PinFin direct liquid-cooled baseplate is used to enhance thermal dissipation, lowering the junction temperature of SiC chips and improving reliability and operational lifespan of the module.

Based on the above design, the packaging structure provided in the present invention improves electrothermal performance of multi-chip power modules, reduces module size, and breaks parallel SiC chip number limitations, significantly improving the current capacity and power density of the existing SiC power semiconductor module and making it ideal for high-power applications like rail traction and flexible DC transmission (1.7 kV˜6.5 kV single-switch modules). Moreover, the packaging structure proposed in this invention remains compatible with conventional processes such as soldering, wire bonding, and potting encapsulation. With the mature fabrication methodology, this solution is highly suitable for large-scale industrial adoption in practical engineering applications.

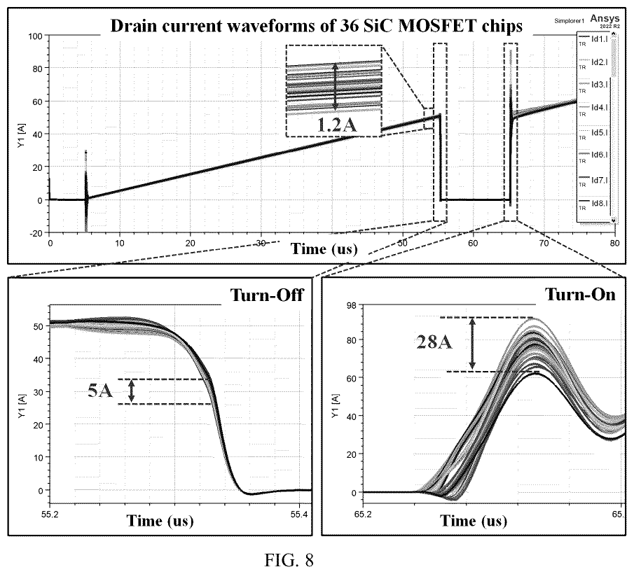

As shown in FIG. 7, the 3.3 kV/2000 A SiC power semiconductor module provided in the embodiment of this invention measures approximately 170×110mm. Compared to commercially available kiloampere-level single-switch Si IGBT power semiconductor modules (190×140 mm), the size is reduced by nearly 30%, effectively improving power density. As shown in FIG. 8, Ansys Q3D and Simplorer electromagnetic co-simulation verified excellent static and dynamic current sharing among the 36 parallel SiC MOSFET chips. The bus voltage of the double-pulse test conditions is 1700 V, and the load current is 1800 A. The static current max difference of the 36 parallel SiC MOSFET chips is 1.2 A (the imbalance <2.5%). The dynamic current max difference is 28 A (the imbalance <40%).

The packaging structure for a kiloampere-level single-switch SiC power semiconductor module is a high-performance design for high-voltage, high-current applications. The specific packaging structure and working principles of components are as follows:

Power Input and Output: source power terminals (4, 6, 8) and drain power terminals (5, 7, 9) are distributed on the first power DBC substrate (10) and second power DBC substrate (11). These terminals provide electrical input and output to the SiC chips.

SiC Chip Connections: Each power DBC substrate has six parallel-connected SiC chips. These chips are connected to the source power terminals via power source bonding wires/copper regions and to the drain power terminals via drain copper regions.

Signal Transmission & Control: the gate signal terminal (2), the Kelvin source signal terminal (1), and the Kelvin drain signal terminal (3) are mounted on the signal DBC substrate (12), responsible for transmitting control signals to the SiC chips. These signal terminals connect to the gate pads of the SiC chips via gate bonding wires/copper regions, enabling precise control of the SiC chips. Additionally, integrated gate resistors (19) are placed on the gate copper regions and connected to the SiC chips via gate bonding wires, suppressing gate parasitic oscillations in parallel chips, improving dynamic current sharing, and enhancing reliability.

Thermal Solution: all signal DBC substrates and power DBC substrates are connected to a PinFin direct liquid-cooled baseplate (13). This baseplate design utilizes PinFin technology to achieve direct liquid cooling, reducing the junction-to-fluid thermal resistance of SiC chips and improving the overall thermal performance of the SiC power module.

Enclosure & Protection: the entire packaging structure is installed in a housing (30), which, together with the potting silicone gel, provides electrical insulation and mechanical protection while preventing intrusion from external contaminants such as dust and moisture, ensuring stable operation of the device even in harsh environments.

The design idea of the packaging structure is to optimize the electrical connections and physical layout to improve the current capacity, power density, and reliability of the power semiconductor module for high-voltage, high-current applications. At the same time, the design incorporates considerations for fault diagnosis in practical applications, enabling online condition monitoring through integrated signal terminals.

The above described are only preferred embodiments of the present invention. The protection scope of the present invention is not limited to this. Any modifications, equivalents, or improvements made by those skilled in the art within the technical scope disclosed herein and consistent with the inventive principles shall fall into the protection of this patent.

What is claimed is:

1. A packaging structure for a kiloampere-level single-switch SiC power semiconductor module, comprising:
multiple source power terminals and drain power terminals, distributed on multiple power DBC substrates, for providing power output and input to the module;
multiple parallel-connected SiC chips located on the same or different power DBC substrates, each chip connected to a corresponding source power terminal via the power source bonding wire of each chip and to a corresponding drain power terminal via the drain copper region;
the signal DBC substrate, on which a Kelvin source signal terminal, a gate signal terminal, and a Kelvin drain signal terminal are placed, for receiving and transmitting control signals of the module;
the baseplate, fixedly connected to the power DBC substrates and the signal DBC substrate, for effectively conducting heat generated by the SiC chips to ensure high-reliability operation of the module;
the housing, together with potting silicone gel, encapsulates and protects all the above components to ensure electrical insulation and provide mechanical support.

2. The packaging structure for a kiloampere-level single-switch SiC power semiconductor module according to claim 1, wherein the SiC power semiconductor module comprises a total of 6 power DBC substrates, each of which is populated with n parallel-connected SiC chips, where n≥6, such that the entire SiC power semiconductor module comprises a total of 6*n parallel-connected SiC chips.

3. The packaging structure for a kiloampere-level single-switch SiC power semiconductor module according to claim 2, wherein the power DBC substrate comprises a drain, a power source, a Kelvin source, and gate copper regions; wherein:
the drain copper region is U-shaped, with an opening of the drain copper region enclosing a rectangular power source copper region;
the parallel-connected SiC chips are evenly spaced on the drain copper region and symmetrically arranged about the vertical centerline of the U-shape;
the gate and Kelvin source copper regions are also U-shaped, with openings of the gate and Kelvin source copper regions oriented opposite to an opening of the drain copper region, and enclose the entire drain-source copper region.

4. The packaging structure for a kiloampere-level single-switch SiC power semiconductor module according to claim 3, wherein:
the gate pad of each SiC chip is connected in series with an integrated gate resistor via a bonding wire;
multiple sets of split gate copper regions connected to the integrated gate resistor are arranged on two straight lines or a single straight line and electrically interconnected via long bonding wires with continuous bonding points;
additionally, if the Kelvin circulating current is large, in this case, each Kelvin chip's source bonding wire of each SiC chip needs to be connected in series with a Kelvin source resistor, arranged in the same manner as the integrated gate resistor.

5. The packaging structure for a kiloampere-level single-switch SiC power semiconductor module according to claim 4, wherein:
the power source bonding wires and the gate/Kelvin source bonding wires of the parallel-connected SiC chips are bonded in opposite directions, thereby decoupling the drive circuit and the power circuit, minimizing the impact of common-source parasitic inductance, and fully leveraging the high switching speed advantage of the SiC chips.

6. The packaging structure for a kiloampere-level single-switch SiC power semiconductor module according to claim 3, wherein:
a common drain current collection point for each of the parallel-connected SiC chip current branches on the power DBC substrate is located at the vertical centerline of the drain copper region;
a common source current collection point is located near the center of the power source copper region;
the length and the angle of the power source bonding wires for each parallel-connected SiC chip are precisely adjusted to improve static and dynamic current-sharing performance among the multiple chips.

7. The packaging structure for a kiloampere-level single-switch SiC power semiconductor module according to claim 6, wherein:
the drain and source power terminals are symmetrically structured and placed at the common drain and common source current collection points of two power DBC substrates, respectively, forming a “sub-switch” structure.

8. The packaging structure for a kiloampere-level single-switch SiC power semiconductor module according to claim 7, wherein:
three “sub-switches” are formed by arranging one “sub-switch” at equal intervals according to a predetermined spacing;
the gate, Kelvin source, and Kelvin drain signal terminals are placed on three identical signal DBC substrates;
the signal DBC substrate and the power DBC substrates are three-layer structures which consist of an upper copper layer, a ceramic layer, a lower copper layer, and are connected to the baseplate;
the drive circuits of all parallel-connected SiC chips are connected by the gate and Kelvin source signal terminals via copper wires or bonding wires to form a drive loop electrical connection;
the Kelvin drain signal terminal and the DBC substrates are also connected to the drain copper region of the power DBC substrate via bonding wires.

9. The packaging structure for a kiloampere-level single-switch SiC power semiconductor module according to claim 1, wherein:
the SiC chips in the kiloampere-level single-switch SiC power semiconductor module consist entirely of SiC MOSFET chips or a proportional combination of SiC MOSFET chips and SiC SBD chips.

10. A packaging method for a kiloampere-level single-switch SiC power semiconductor module, comprising the following steps:
S101: soldering or sintering SiC chips and integrated gate/Kelvin source resistors onto power DBC substrates;
S102: performing wire bonding for the gate, Kelvin source, and power source bonding wires of the SiC chips;
S103: soldering the drain and source power terminals and the gate, Kelvin source, and Kelvin drain signal terminals onto the power DBC substrates and signal DBC substrate, respectively, while soldering or sintering the power DBC substrates and the signal DBC substrate onto the baseplate;
S104: performing wire bonding for interconnect bonding wires between DBC substrates;
S105: assembling a housing of the SiC power semiconductor module and performing potting encapsulation.
